(19) United States
(12) Patent Application Publication
(10) Pub. No.: US 2013/0342235 A1
(43) Pub. Date: Dec. 26, 2013

(54) PROBE CARD

(71) Applicant: SEDICON Co., Ltd., Gunpo-si (KR)

(72) Inventor: Chung-Soo HAN, Seoul (KR)

(21) Appl. No.: 13/903,183

(22) Filed: May 28, 2013

(30) Foreign Application Priority Data
Jun. 25, 2012 (KR) 10-2012-0067991

(51) Int. Cl. G01R 1/073

(52) U.S. Cl. CPC G01R 1/073
USPC 324/756.03

(57) ABSTRACT

The present invention relates to a probe card having improved electrical characteristics and mechanical durability of a portion where the probe needle and bump electrode of the probe card come into contact with each other.

### CROSS REFERENCE TO RELATED APPLICATION

This application claims the benefit of Korean Patent Application No. 10-2012-0067991, filed Jun. 25, 2012, which is hereby incorporated by reference in its entirety into this application.

### BACKGROUND OF THE INVENTION

1. Technical Field

The present invention relates to a probe card and, more particularly, to a probe card having improved electrical characteristics and mechanical durability of a portion where the probe needle and bump electrode of the probe card come into contact with each other.

2. Description of the Related Art

In general, when fabricating electrical circuit devices, such as semiconductor integrated circuit devices, a test is performed in order to check whether or not the electrical characteristics of the electrical circuit device coincide with a design.

Equipment used in this test is a semiconductor test device (or probe station), and a probe card is mounted on this equipment. The probe card functions to deliver various electrical signals within the semiconductor test device to a semiconductor device to be tested.

An integrated circuit for driving a Liquid crystal display Driver Integrated circuit (LDI) can be configured in a Chip-On Film (COF) form. Finally, the LDI is tested for defects of electrical characteristics.

The final test process is performed using a tester in which various measurement devices are embedded in a computer, that is, a semiconductor test device, and a prober station on which a probe card capable of electrically contacting a semiconductor device having a COF form, that is, the subject of test, is mounted.

From among probe cards, a vertical type probe card is being used a lot because of advantages in that the vertical type probe card can perform a probe test on several semiconductor devices having a finer pitch at the same time, as compared with a cantilever type probe card, and the vertical type probe card is cheaper than a probe card using an MEMS method.

Unlike in the probe needles of the cantilever type probe card, in the vertical type probe card, the lower ends of probe needles coming into contact with the contact points of a semiconductor device have a vertical form. Furthermore, in the vertical type probe card, connection wires that couple the board and bump electrodes of the probe card and the probe needles can be made of materials having excellent electrical conductivity and processing property.

A contact property between the bump electrodes and connection wires of this interposer board can be significantly deteriorated over time due to repeated contacts with semiconductor devices. That is, a problem, such as that a contact portion is abraded or deformed or is contaminated by alien substances, can occur.

The contact property problem of the probe needles or contact parts thereof according to use of the probe card can be connected directly with the durability of the entire probe card.

### SUMMARY OF THE INVENTION

Accordingly, the present invention has been made keeping in mind the above problems occurring in the prior art, and an object of the present invention is to provide a probe card having an improved contact property between the probe needle and bump electrode of the probe card, which come into contact with each other.

In accordance with an aspect of the present invention, the above and other objects can be accomplished by the provision of probe card comprising an interface board having an opening and a circuit part, a plurality of connection wires configured to have first ends bonded to contact points of the circuit part of the interface board, an interposer configured to have the connection wires penetrate through the interposer and to have second ends of the connection wires exposed from a bottom surface of the interposer, thus forming bump electrodes, and placed in the opening of the interface board, a plurality of probe needles configured to have upper ends connected to the respective bump electrodes provided on the bottom surface of the interposer and to have lower ends extended downward and at least one support plate configured to have the probe needles inserted into and mounted on the support plate so that the upper ends of the probe needles are exposed upward from the support plate and the lower ends of the probe needles are exposed downward from the support plate, wherein the upper end of each of the probe needles connected to the bump electrodes of the interposer comprises a rhodium plating layer plated with rhodium.

And The probe needle may be a cobra type probe needle.

And the upper end of the probe needle may be plated with nickel and then plated with rhodium.

And the bump electrodes of the interposer may be plated with rhodium.

And The bump electrodes may be plated with nickel and then plated with rhodium.

And the probe needle may comprise palladium as an alloy component, and the palladium is 20 to 50 wt %.

And the alloy component of the probe needle may further comprise copper (Cu) or silver (Ag).

And the upper end of the probe needle may be subject to rounding processing and then plated with rhodium.

And the thickness of the rhodium plating layer of the probe needle may be 0.5 to 2.5 μm.

And the thickness of the nickel plating layer of the probe needle may be 0.5 to 2.5 μm.

And the thickness of the nickel or rhodium plating layer of the bump electrode of the interposer may be 0.5 to 2.5 μm.

And the plating of the probe needles is dipped into an electro bath in a state in which a plurality of the probe needles is mounted on a jig for plating.

And the support plate may comprise an upper support plate and a lower support plate and comprises a hollow part between the upper support plate and the lower support plate.

### BRIEF DESCRIPTION OF THE DRAWINGS

FIG. 1 shows an example of semiconductor devices to be tested using a probe card according to the present invention;

FIG. 2 is a perspective view of the probe card according to the present invention;

FIG. 3 is an exploded perspective view of the probe card according to the present invention;

FIG. 4 is a cross-sectional view of the probe card shown in FIG. 3;

FIG. 5 shows a process of molding a probe needle according to the present invention;

FIG. 6 is a photographed image of the top surface ‘hes’ of the probe needle according to the present invention; and

FIGS. 7 and 8 are enlarged cross-sectional views of a portion where the probe needle and bump electrode of the probe card come into contact with each other according to the present invention.

### DETAILED DESCRIPTION

Some exemplary embodiments of the present invention are described in detail with reference to the accompanying drawings.

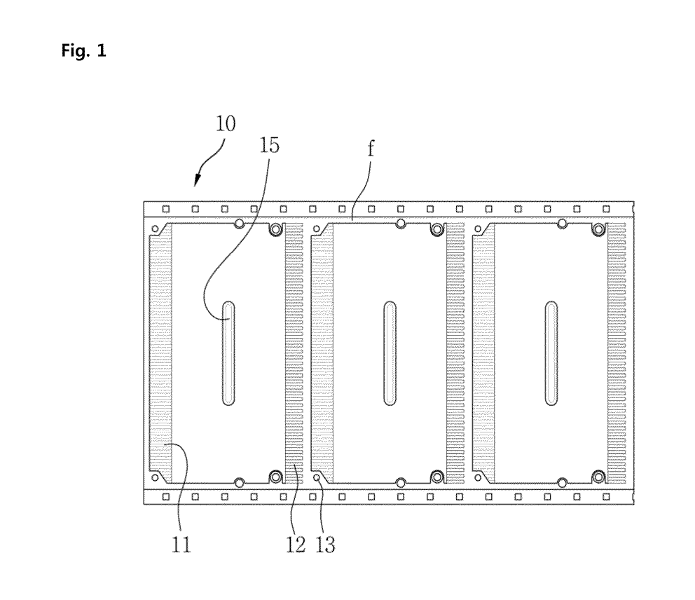

FIG. 1 shows an example of semiconductor devices 10 to be tested using a probe card 1000 according to the present invention. A Liquid crystal display Driver Integrated circuit (LDI) is shown as an example of the semiconductor device 10. The LDI can be configured in the form of a Chip-On Film (COF). Furthermore, a plurality of LDIs can be formed into one film. That is, the semiconductor devices 10 can have a COF form in a process, such as an Electrical Die Sorting (hereinafter referred to as an EDS) test for testing the electrical characteristics of the semiconductor devices 10, before the semiconductor devices 10 are finally packaged.

In this case, the waste of unnecessary packaging can be prevented by checking a defect in the semiconductor device 10.

Furthermore, a probe test using a vertical type probe card according to the present invention can be applied to a case where the plurality of semiconductor devices 10 formed on one film is tested before packaging the semiconductor devices 10 because the plurality of semiconductor devices 10 can be tested at the same time.

In the embodiment shown in FIG. 1, for example, three semiconductor devices 10 are provided on one film ‘f’.

Each semiconductor device 10 includes an input part 11, an output part 12, and a semiconductor 15 functioning as a central processing part. The semiconductor device 10 further includes a pattern (not shown) for coupling the input part 11, the semiconductor 15, and the output part 12 on the film ‘f’.

The probe card 1000 according to the present invention includes a plurality of probe needles having a fine pitch. The probe needles can precisely come into contact with respective contact points that form the input part 11 or the output part 12 of the semiconductor device 10 so that a probe test can be performed.

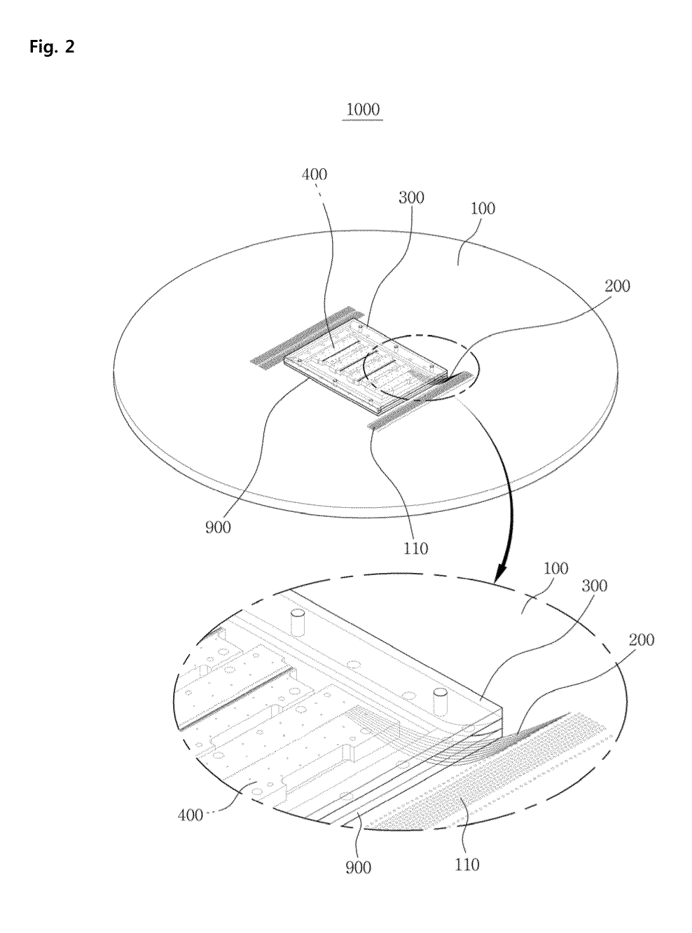

FIG. 2 is a perspective view of the probe card 1000 according to the present invention.

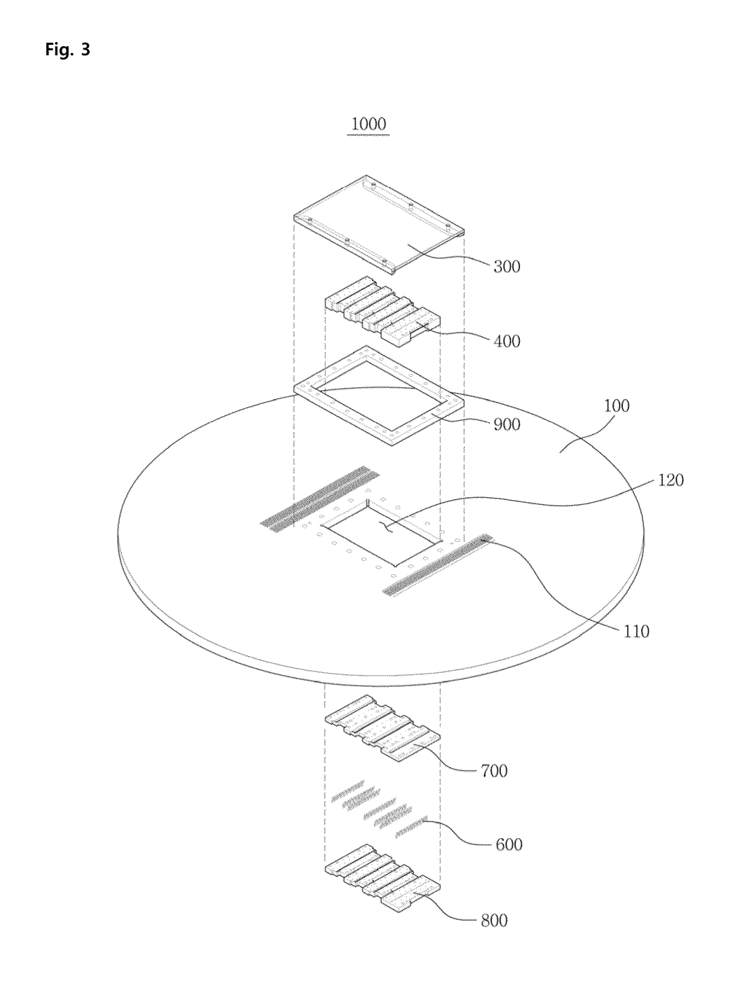

The probe card 1000 according to the present invention includes an opening (refer to 120 of FIG. 3) and an interface board 100 having a circuit part (not shown) provided in the circumference of the opening 120.

The interface board 100 can include an interposer 400 disposed at its central part, the opening 120 configured to have probe needles disposed on the upper and lower sides, the circuit part (not shown) disposed in the circumference of the opening 120 and electrically connected to a tester or a test device, and a terminal part 110 having a plurality of terminals corresponding to the circuit part.

One ends of connection wires 200 are bonded to the terminal part 110 of the interface board 100, and the other ends of the connection wires 200 are bonded to the interposer 400 to be described later. The connection wires 200 function to electrically couple the interposer 400 and the interface board 100.

The interposer 400 can be disposed under a cover member 300 disposed over the opening 120.

The connection wires 200 are penetrated into the interposer 400 and then mounted on the interposer 400. Bump electrodes (not shown) formed at the lower ends of the connection wires 200 can be provided on the bottom surface of the interposer 400.

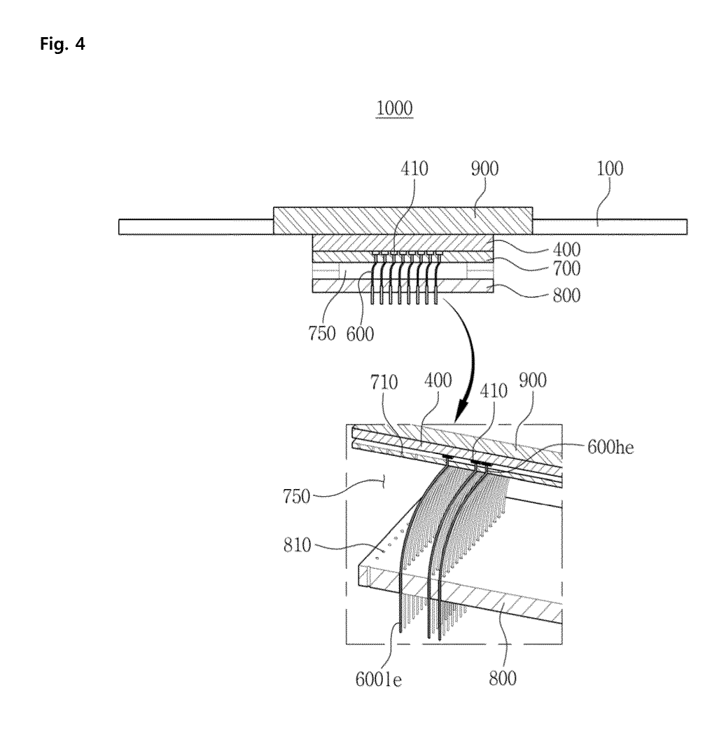

FIG. 3 is an exploded perspective view of the probe card 1000 according to the present invention, and FIG. 4 is a cross-sectional view of the probe card 1000 shown in FIG. 3.

The probe card 1000 according to the present invention can include the opening 120, the interface board 100 configured to have the circuit part (not shown) provided in the circumference of the opening 120, and a mounting member 900 disposed in the opening 120 and configured to provide a place on which the interposer 400, etc. is mounted and to have a ring form for hardness reinforcement.

The probe card 1000 can include a plurality of the connection wires (refer to 200 of FIG. 2) configured to have one ends bonded to the contact points of the circuit part of the interface board 100, the interposer 400 bonded to the other ends of the connection wires 200 and configured to have bump electrodes 410 corresponding to the other ends of the connection wires (refer to 200 of FIG. 2), respectively, provided on the bottom surface thereof, a plurality of probe needles 600 configured to come into contact with the respective bump electrodes 410 of the interposer 400 and mounted in the up and down directions of the opening 120 of the interface board 100, and one or more support plates 700 and 800 configured to have a through hole through which the probe needles 600 penetrate formed therein, to have the probe needles 600 penetrate therethrough, and to support the probe needles 600.

One ends of the connection wires 200 are coupled with the terminal part (refer to 110 of FIG. 2) provided in the circumference of the opening 120 of the interface board 100, and the other ends of the connection wires 200 are bonded to the bump electrodes 410 of the interposer 400.

The interposer 400 functions to couple the probe needles 600 and the terminal part 110 through the connection wires 200 because the probe needles 600 cannot be directly connected to the terminal part 110 of the interface board 100. The probe needles 600 are disposed at intervals corresponding to that of the input and output parts of the semiconductor device to be tested, but the interval between the probe needles 600 is too dense according to a reduction in the size of semiconductor devices. Thus, the probe needles 600 are provided because they cannot directly come into contact with the terminal part 110 of the interface board 100.

That is, the interposer 400 can serve as connection means for coupling the probe needles 600 and the connection wires 200.

Furthermore, as shown in FIGS. 3 and 4, the probe needles 600 can be supported by the one or more support plates 700 and 800 provided under the interposer 400. The one or more support plates 700 and 800 are provided in order to support the probe needles 600 vertically.

The probe needles 600 included in the probe card according to the present invention are not bonded to the bump electrodes 410, and the probe needles 600 can be configured to come in contact with the bump electrodes 410 when testing semiconductor devices depending on a test on the semiconductor itself. Here, cobra type probe needles for preventing the deformation of the probe needles and providing specific repulsive power can be used when the probe card for testing a semiconductor is stroked (contacted).

The one or more support plates 700 and 800 can be provided in order to separately support the upper and lower ends of the cobra type probe needles using the cobra type probe needles.

From among the one or more support plates 700 and 800, the upper support plate 700 supports the upper ends of the probe needles 600 and the lower support plate 800 supports the lower ends of the probe needles 600 so that the lower ends of the probe needles 600 are exposed downwardly from the bottom of the lower support plate 800.

The support plates can include the upper support plate 700 and the lower support plate 800. The upper support plate 700 and the lower support plate 800 can be spaced apart from each other and stacked. Or, the upper support plate 700 and the lower support plate 800 can be stacked so that cobra type probe needles can provide an elastically deformed space therebetween, and a hollow part 750 can be provided between the upper support plate 700 and the lower support plate 800 in the state in which the upper support plate 700 and the lower support plate 800 are assembled.

Accordingly, the upper support plate 700 and the lower support plate 800 can include through holes 710 and 810 through which the upper and lower ends of the probe needles 600 are exposed up and down.

As shown in FIG. 4, the bump electrodes 410 formed by making electrodes the lower ends of the connection wires can be provided on the bottom surface of the interposer 400.

Accordingly, when the probe card and a semiconductor device to be tested are brought to approach each other, pressurized, and then tested, the lower ends 600le of the probe needles 600 come into contact with the input or output terminal of the semiconductor device to be tested, and the upper ends 600he of the probe needles 600 exposed upwardly from the through holes 710 of the upper support plate 700 can come into contact with the bump electrodes 410 disposed on the bottom surface of the interposer 400.

The probe needles and the bump electrodes of this probe card can be abraded when they come in contact with each other repeatedly or can be contaminated with alien substances. If the contact portions are abraded or contaminated, electrical performance for a probe test may not be secured. This is closely related to the durability of the probe card.

The connection wires of the probe card according to the present invention can be made of copper (Cu) as a main component. The probe needles included in the probe card according to the present invention can be made of palladium (Pd) as a main component. Accordingly, the connection wires and the probe needles can be suddenly abraded when the number of probe tests is increased, or a contact property between the connection wires and the probe needles can be suddenly deteriorated due to the attachment of alien substances, for example, contact resistance can be increased.

In the probe needles and the probe card according to the present invention, in order to solve the problems, a contact portion between the probe needle and the bump electrode is reinforced by a metallic plating method. The metallic plating method is described in detail later.

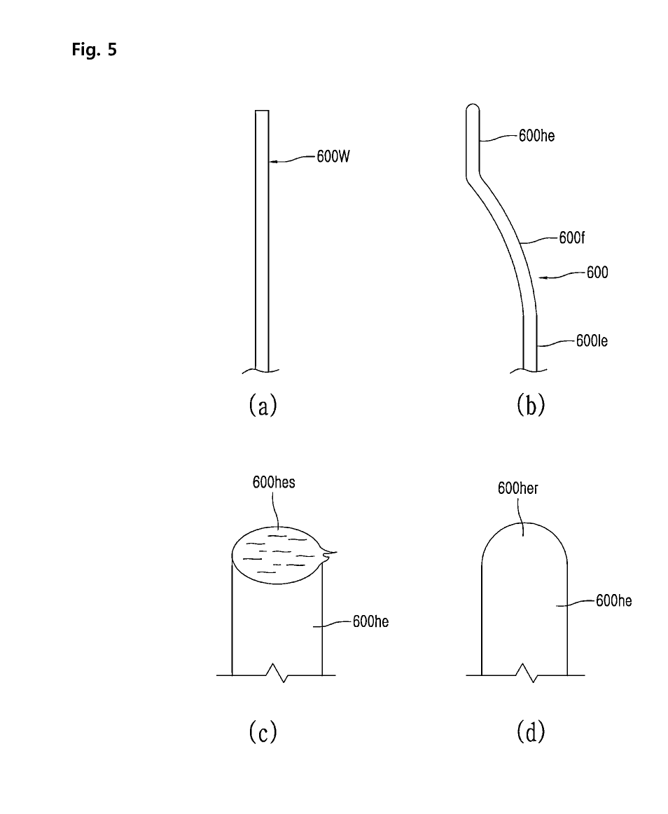

FIG. 5 shows a process of molding a probe needle according to the present invention.

More particularly FIG. 5(a) shows a probe needle wire 600W cut in a predetermined length, FIG. 5(b) shows a state in which an elastic part 600f other than the upper end 600he and the lower end 600le of the probe needle has been molded, FIG. 5(c) is an enlarged view of the upper end 600he of the molded probe needle, and FIG. 5(d) shows a state in which the upper end 600he of the probe needle shown in FIG. 5(c) has been subjected to rounding processing 600her.

As shown in FIG. 5(a), the probe needle wire 600W can have a wound wire form before the probe needle wire 600W is processed. The probe needle wire 600W can be cut at a predetermined interval and used as the materials of probe needles. The cross section of the probe needle wire 600W before molding can have a regular form.

As shown in FIG. 5(b), the upper end 600he of the probe needle is a portion with which the above-described bump electrode comes into contact, and the lower end 600le of the probe needle is a portion with which the terminal of the above-described semiconductor device comes into contact.

A portion that couples the upper end 600he and the lower end 600le of the probe needle shown in FIG. 5(b) is the elastic part 600f. When the lower end 600le of the probe needle is brought in contact with and pressurized against the lower end of each semiconductor device in order to test the semiconductor device, the elastic part 600f is elastically deformed, thus providing elastic repulsive force, so the bump electrodes of the interposer can be stably brought in contact with the terminals of the semiconductor device.

The elastic part 600f may be pressurized and molded by a press, etc. and can be molded in a sheet form so that the cross section of the elastic part 600f can be elastically deformed easily.

Raw materials for probe needles have a wound wire form, and thus there is a need for a process of cutting the wound wire in a predetermined length in order to manufacture probe needles. As shown in FIG. 5(c), in the cutting process, a burr ‘b’ may remain on a surface or at the edge of the upper end (or top surface ‘hes’) of the probe needle, and thus the upper end of the probe needle can have a coarse form. Since the upper end of the probe needle repeatedly comes into contact with the bump electrode, the object of contact can be damaged by a burr remaining on the coarse surface or surface, or alien substances can be adsorbed on the object of contact.

In order to prevent this problem, rounding processing for forming the rounding portion 600her by trimming the coarse surface or surface in the state in which the upper end 600he of the probe needle has been cut can be performed on the probe card according to the present invention, as shown in FIG. 5d.

The rounding processing for the upper end 600he of the probe needle can help to secure uniform quality in a plating process to be described later.

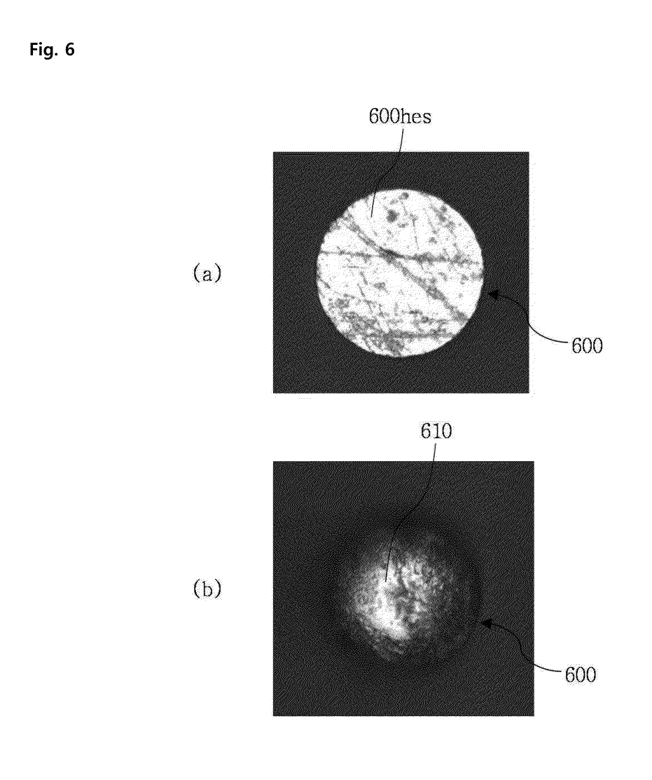

FIG. 6 is a photographed image of the top surface ‘hes’ of the probe needle according to the present invention. More particularly, FIG. 6(a) shows a photographed image of the top surface ‘hes’ before rounding processing is performed on the upper end of the probe needle, and FIG. 6(b) shows a photographed image of the top surface after rounding processing is performed on the top surface of the probe needle and the upper end of the rounding-processed probe needle is plated with rhodium (Rh).

As shown in FIG. 5(c), the top surface ‘hes’ of the probe needle on which additional processing has not been performed can have a coarse surface state attributable to various burrs or scratches. This coarse surface can be contaminated with alien substances in a process of testing a semiconductor device through repeated contacts with a bump electrode, so contact resistance can be increased. A probe needle made of palladium (Pd), silver (Ag), or copper (Cu) can be easily abraded or deformed because of weak strength.

Accordingly, rounding processing is performed on the upper end of the probe needle according to the present invention and a rhodium (Rh) plating layer 610 is provided in order to reduce roughness on the top surface ‘hes’ of the probe needle and minimize the abrasion or deformation of the upper end of the probe needle. Accordingly, the durability of both the probe needles and the probe card including the probe needles can be increased.

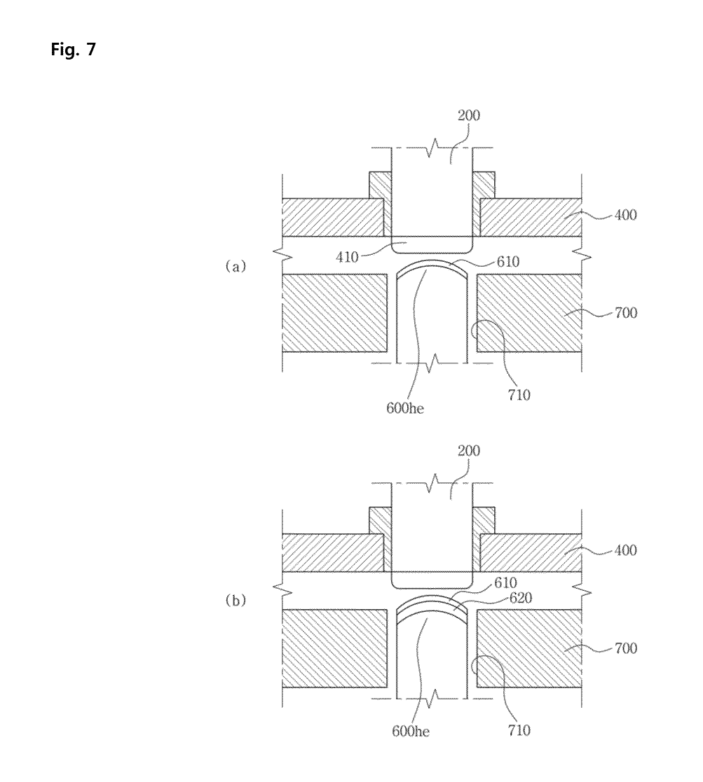

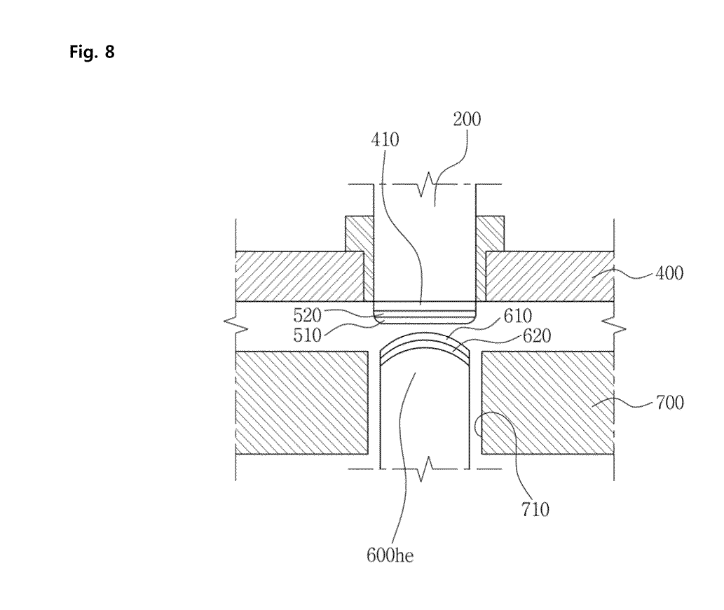

FIGS. 7 and 8 are enlarged cross-sectional views of a portion where the probe needle and bump electrode of the probe card come into contact with each other according to the present invention.

More particularly, FIG. 7(a) shows an embodiment in which the upper end of the probe needle of the probe card has been plated with rhodium (Rh), and FIG. 7(b) shows an embodiment in which the upper end of the probe needle of the probe card has been plated with nickel (Ni) and rhodium (Rh). FIG. 8 shows an embodiment in which the upper end of the probe needle and the bump electrode, of the probe card, has been plated with nickel (Ni) and rhodium (Rh).

The upper end of the probe needle of the probe card according to the present invention is plated with rhodium (Rh) in order to prevent the deterioration of the contact property attributable to repeated contacts between the probe needle and the bump electrode of the interposer.

The probe needle mounted on the probe card according to the present invention can be made of a palladium (Pd)-based alloy, and palladium (Pd) of the alloy components of the probe needle can be 20 to 50 wt %.

In the embodiments shown in FIGS. 7 and 8, the palladium (Pd) component of the probe needle was in a range of 34 to 36 wt %, and the alloy components of the probe needle can further include copper (Cu) or silver (Ag). Palladium (Pd), silver (Ag), or copper (Cu) has an excellent processing property and electrical conductivity, but has weak mechanical strength and thus cannot sufficiently guarantee durability. In the probe card according to the present invention, the contact portion of the probe needle can be reinforced by plating the upper end of the probe needle with rhodium (Rh).

Rhodium (Rh) is platinum group element transition metal belonging to the ninth group in the periodic table. Rhodium (Rh) has properties, such as that the symbol of element is Rh, an atomic number is 45, an atomic weight is 102.906, a melting point is 1963, a boiling point is 3727, and specific gravity is 12.41. Rhodium (Rh) has excellent strength, but it is expensive. For this reason, rhodium (Rh) is not used as the materials of an alloy that forms the contact portion of the probe needle and the probe card according to the present invention, but the rhodium (Rh) plating layer 610 is limitedly provided to only the contact portion of the probe needle and the bump electrode. Accordingly, the amount of rhodium (Rh) used can be minimized, and a strength reinforcement effect using rhodium (Rh) can be maximized. Furthermore, rhodium (Rh) can secure a material characteristic suitable for coating the contact portion of the probe needle because it has excellent mechanical hardness and excellent electrical conductivity.

The abrasion or deformation of the upper end portion of the probe needle plated with rhodium (Rh) due to repeated contacts can be minimized because the strength of the upper end portion can be significantly increased. Furthermore, since the hardness of the probe needle is enhanced, the durability of the probe card can be improved and a cost necessary to test a semiconductor device can be minimized.

The rhodium (Rh) plating layer 610 of the probe needle can have a thickness of 0.5 to 2.5 μm. As in the embodiment shown in FIG. 7 or 8, the thickness of the rhodium (Rh) plating layer 610 preferably can be 1.4 to 1.6 μm.

Furthermore, in order to improve the quality of rhodium (Rh) plating, the upper end of the probe needle can be first plated with nickel (Ni) before the upper end 600he of the probe needle is plated with rhodium (Rh).

After forming a nickel (Ni) plating layer 620 by plating the upper end of the probe needle with nickel (Ni), the rhodium (Rh) plating layer 610 can be formed by plating the nickel (Ni) plating layer 620 with rhodium (Rh).

When the nickel (Ni) plating layer 620 is formed, the quality of rhodium (Rh) plating can be improved because surface roughness can be reduced.

The nickel (Ni) plating layer 620 of the probe needle can have a thickness of 0.5 to 2.5 μm. As in the embodiment shown in FIG. 7 or 8, the thickness of the nickel (Ni) plating layer 620 preferably can be 1.4 to 1.6 μm corresponding to the thickness of the rhodium (Rh) plating layer 610.

Unlike the embodiment of FIG. 6, the embodiment of FIG. 8 shows an example in which the same plating layer is formed in the bump electrode 410 formed at the lower end of the connection wire 200.

The embodiment of FIG. 8 illustrates a case where both a nickel (Ni) plating layer 520 and a rhodium (Rh) plating layer 510 are provided in the bump electrode, but only rhodium (Rh) plating other than nickel (Ni) plating may be performed as in FIG. 7(a).

The contact property of the bump electrode 410 can also be deteriorated due to repeated contacts with the upper end of the probe needle. Accordingly, the deterioration of the contact property can be prevented by reinforcing the strength of the bump electrode 410 through rhodium (Rh) plating.

Table 1 shows open ratios of electrical connections between the probe needle and the bump electrode according to the overdrive (O/D) depths of strokes in a test process for a semiconductor device using the probe card according to the present invention.

The O/D depth refers to the depth of a stroke, assuming that the state in which the probe needle first comes into contact with the terminal of a semiconductor device to be tested by bringing the probe card and the semiconductor device in contact with each other is 0 μm O/D.

In experiments, a contact property between the probe needle and the bump electrode was tested by testing a semiconductor device to be tested, while increasing the O/D depth to 100 μm, 200 μm, and 300 μm, in the state in which the upper end of the probe needle had been subject to non-plating A, rhodium (Rh) plating (brush plating B), and rhodium (Rh) plating (electro-bath plating C).

When the open ratio is high, it means that a contact property (i.e., electrical connection) between the probe needle and the bump electrode is low. From Table 1, it can be seen that the cases B and C where rhodium (Rh) plating was performed on the upper end of the probe needle forming the probe card have a higher contact property than the case A where rhodium (Rh) plating was not performed on the probe needle.

That is, it can be seen that the contact property in the same O/D depth is generally high in the plating state through repeated experiments.

It can also be seen that the case C where an electro-bath plating was performed in the state in which the upper end of the probe needle was dipped into an electro bath for plating has a better contact property than the case B where brush plating was performed on the upper end of the probe needle using a brush directly, from among methods of forming the rhodium (Rh) plating layer at the upper end of the probe needle.

A probe needle may have low plating efficiency because the size of the probe needle is very small. If plating is performed in the state in which a plurality of probe needles has been mounted on a jig for plating, a large number of probe needles can be plated at the same time. Accordingly, a number of probe needles having fine sizes can be plated effectively.

In the case of the electro-bath plating, a plurality of probe needles can be dipped into an electro bath for plating and plated in the state in which the plurality of probe needles has been mounted on a jig for plating. Accordingly, the quality of the rhodium (Rh) plating layer can become uniform, and a plating yield can be improved significantly.

TABLE 1

| | | Rhodium (Rh) brush | Rhodium (Rh) electro- |
|---|---|---|---|
| | Non-plating (A) | plating (B) | bath plating (C) |
| Open | about 40% | about 25% | about 10% |
| ratio | (100 μm O/D) | (100 μm O/D) | (100 μm O/D) |
| | about 10% | about 7% | about 2% |
| | (200 μm O/D) | (200 μm O/D) | (200 μm O/D) |
| | about 5% | about 2% | about 0.1% |
| | (300 μm O/D) | (300 μm O/D) | (300 μm O/D) |

From Table 1, it can be seen that the open ratios according to the same O/D depth are reduced to meaningful ratios in non-plating (A), rhodium (Rh) brush plating (B), and rhodium (Rh) electro-bath plating (C), respectively, and thus an electrical contact property between the probe needle and the bump electrode is improved.

It can also be seen that the contact property is effectively improved in the case of non-plating (A) and the case of rhodium (Rh) brush plating (B) and that a difference in the contact property between the case of non-plating (A) and the case of rhodium (Rh) electro-bath plating (C) is further great.

Furthermore, it can be seen that in the case of rhodium (Rh) electro-bath plating (C), when the O/D depth is 300 μm, the open ratio is very low, that is, about 0.1%, which means that an error rate is very low or can be neglected when a test is performed.

As a result, as shown in FIG. 1, in the probe card according to the present invention, the probe needle is not easily abraded or deformed because the rhodium (Rh) plating layer is formed at the upper end of the probe needle. Accordingly, the durability of the probe needle can be improved, and thus the lifespan of the probe card can be improved. Furthermore, since the rhodium (Rh) plating layer is included at the upper end of the probe needle, alien substances can be prevented from being interposed between the probe needle and the bump electrode. As a result, durability can be improved and surface roughness can be lowered, with the result that an electrical contact property in a semiconductor test process can be improved.

Furthermore, in the probe card according to the present invention, surface roughness at a contact portion between the upper end and the bump electrode of the probe needle can be reduced and electrical connection according to overdrive for a test can be facilitated by performing rounding processing on the upper end of the probe needle. Furthermore, the plating quality of the rhodium (Rh) plating layer can be improved because the nickel (Ni) plating layer is formed by plating the upper end of the probe needle with nickel (Ni) and then plating the upper end of the nickel (Ni) plating layer with rhodium (Rh).

In the probe card according to the present invention, the probe needle is not easily abraded or deformed because the rhodium (Rh) plating layer is formed at the upper end of the probe needle. Accordingly, the durability of the probe needle can be improved, and thus the lifespan of the probe card can be improved.

Furthermore, in the probe card according to the present invention, surface roughness on the top surface of the probe needle that comes into contact with the bump electrode is reduced because the rhodium (Rh) plating layer is formed at the upper end of the probe needle. Accordingly, alien substances can be prevented from being interposed between the probe needle and the bump electrode, and a contact property in repeated semiconductor device test can be improved.

Furthermore, in the probe card according to the present invention, surface roughness at a contact portion between the upper end of the probe needle and the bump electrode can be reduced and an electrical contact property according to overdrive for a test can be improved because rounding processing is performed on the upper end of the probe needle.

Furthermore, in the probe card according to the present invention, the plating quality of the rhodium (Rh) plating layer can be improved because the nickel (Ni) plating layer is formed by plating the upper end of the probe needle with nickel (Ni) and then plating the upper end of the nickel (Ni) plating layer with rhodium (Rh).

Furthermore, in the probe card according to the present invention, a contact property between the probe needle and the bump electrode can be further improved by adding the rhodium (Rh) plating layer or the nickel (Ni)-rhodium (Rh) plating layers to the bump electrode that repeatedly comes into contact with the probe needle.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A probe card, comprising:
an interface board having an opening and a circuit part;
a plurality of connection wires configured to have first ends bonded to contact points of the circuit part of the interface board;
an interposer configured to have the connection wires penetrate through the interposer and to have second ends of the connection wires exposed from a bottom surface of the interposer, thus forming bump electrodes, and placed in the opening of the interface board;
a plurality of probe needles configured to have upper ends connected to the respective bump electrodes provided on the bottom surface of the interposer and to have lower ends extended downward; and
at least one support plate configured to have the probe needles inserted into and mounted on the support plate so that the upper ends of the probe needles are exposed upward from the support plate and the lower ends of the probe needles are exposed downward from the support plate,
wherein the upper end of each of the probe needles connected to the bump electrodes of the interposer comprises a rhodium plating layer plated with rhodium.

2. The probe card of claim 1, wherein the probe needle is a cobra type probe needle.

3. The probe card of claim 2, wherein the upper end of the probe needle is plated with nickel and then plated with rhodium.

4. The probe card of claim 1, wherein the bump electrodes of the interposer are plated with rhodium.

5. The probe card of claim 4, wherein the bump electrodes is plated with nickel and then plated with rhodium.

6. The probe card of claim 1, wherein the probe needle comprises palladium as an alloy component, and the palladium is 20 to 50 wt %.

7. The probe card of claim 6, wherein the alloy component of the probe needle further comprises copper (Cu) or silver (Ag).

8. The probe card of claim 1, wherein the upper end of the probe needle is subject to rounding processing and then plated with rhodium.

9. The probe card of claim 8, wherein a thickness of the rhodium plating layer of the probe needle is 0.5 to 2.5 μm.

10. The probe card of claim 3, wherein a thickness of the nickel plating layer of the probe needle is 0.5 to 2.5 μm.

11. The probe card of claim 5, wherein a thickness of the nickel or rhodium plating layer of the bump electrode of the interposer is 0.5 to 2.5 μm.

12. The probe card of claim 1, wherein the plating of the probe needles is dipped into an electro bath in a state in which a plurality of the probe needles is mounted on a jig for plating.

13. The probe card of claim 1, wherein the support plate comprises an upper support plate and a lower support plate and comprises a hollow part between the upper support plate and the lower support plate.
